(19) United States
(12) Patent Application Publication
(10) Pub. No.: US 2023/0154635 A1
(43) Pub. Date: May 18, 2023

(54) NON-INVASIVE LIQUID METAL FLOW MEASUREMENT IN LIQUID METAL FUEL ASSEMBLIES, REACTOR COOLANT PUMPS, AND TEST CARTRIDGES

(71) Applicant: Westinghouse Electric Company LLC, Cranberry Township, PA (US)

(72) Inventors: Jeffrey L. ARNDT, Pittsburgh, PA (US); Paolo FERRONI, Pittsburgh, PA (US); Cory A. STANSBURY, Gorham, ME (US)

(73) Assignee: Westinghouse Electric Company LLC, Cranberry Township, PA (US)

(21) Appl. No.: 17/454,920

(22) Filed: Nov. 15, 2021

(51) Int. Cl. G21C 17/032; H05K 9/00; G01F 1/58

(52) U.S. Cl. CPC G21C 17/032; H05K 9/0081; G01F 1/588

(57) ABSTRACT

A non-invasive eddy current flow meter embedded into a coolant channel for measuring the coolant flow velocity of liquid metal coolant in a nuclear reactor. The eddy current flow meter measures the coolant flow velocity in pool-type nuclear reactors and narrow coolant channels without creating bottlenecks that impede the coolant flow within the nuclear reactors.

### GOVERNMENT CONTRACT

This invention was made with government support under ORNL, LANL—Contract 212107-01 titled Versatile Test Reactor (VTR) Experiment Vehicle Development and Design. The government has certain rights in the invention.

### BACKGROUND

The flow velocity of liquid metal coolant is closely monitored in a nuclear reactor. The rate of flow velocity is directly related the breakdown of reactor components due to the erosion and corrosive properties of the liquid metal coolant. Small spaces like coolant inlets or outlets can be particularly difficult to measure the coolant flow velocity. Traditional eddy current flow meters (ECFMs) are implemented as stand-alone probes that can impede or obstruct the flow of coolant. The stand-alone probes may further restrict coolant flow resulting in inaccurate flow velocity measurements and the accelerated component wear.

### SUMMARY

In various aspects, the present disclosure describes a coolant channel flow meter for measuring the velocity of liquid metal coolant comprising: a primary coil communicably coupled to a constant current alternating current generator; a first secondary coil; a second secondary coil; a coolant channel comprising: the first secondary coil, the primary coil, and the second secondary coil embedded into a cladding walls of the coolant channel, wherein the primary coil is positioned between the first secondary coil and the second secondary coil, and wherein the first secondary coil, the primary coil, and the second secondary coil are configured in a recessed position into the cladding wall; an electromagnetic interference (EMI) shield embedded in the cladding wall, wherein the EMI shield is configured as a continuous barrier between the cladding wall and the exterior circumferential edge of the first secondary coil, the primary coil, and the second secondary coil; and a hollow center channel configured to pass liquid metal coolant through a center defined by the first secondary coil, the primary coil, and the second secondary coil; a control circuit communicably coupled to the primary coil, the first secondary coil, and the second secondary, wherein the control circuit is configured to: generate a constant current alternating current in the primary coil; determine a voltage difference and a phase difference between the first secondary coil and second secondary coil; and determine a velocity of the liquid metal coolant based on the voltage difference and the phase difference between the first secondary coil and second secondary coil, and the liquid metal coolant composition.

In various aspects, the present disclosure describes a system for a test cartridge flow meter for measuring the velocity of test cartridge liquid metal coolant comprising: a primary coil communicably coupled to a constant current alternating current generator; a first secondary coil; a second secondary coil; a propeller drive motor configured to actuate a propeller; a coolant channel comprising: the first secondary coil, the primary coil, and the second secondary coil embedded into a cladding walls of the coolant channel, wherein the primary coil is positioned between the first secondary coil and the second secondary coil, and wherein the first secondary coil, the primary coil, and the second secondary coil are configured in a recessed position into the cladding wall; an electromagnetic interference (EMI) shield embedded in the cladding wall, wherein the EMI shield is configured as a continuous barrier between the cladding wall and the exterior circumferential edge of the first secondary coil, the primary coil, and the second secondary coil; and a hollow center channel configured to allow test cartridge liquid metal coolant to pass through a center defined by the first secondary coil, the primary coil, and the second secondary coil; a control circuit communicably coupled to the primary coil, the first secondary coil, and the second secondary, and the control circuit is configured to: engage the propeller drive motor according to a predetermined coolant velocity; generate a constant current alternating current in the primary coil; determine a voltage differential and a phase differential between the first secondary coil and second secondary coil; and determine a velocity of the liquid metal coolant based on the voltage differential and the phase differential between the first secondary coil and second secondary coil, and the liquid metal coolant composition.

In yet another aspect, the present disclosure describes a system for measuring the flow of liquid metal coolant in a pool-type nuclear reactor, the system comprising: a pool-type nuclear reactor comprising a plurality of submerged coolant channels, the plurality of submerged coolant channels comprising one or more coolant channel flow meters; the one or more coolant channel flow meters comprising: a primary coil communicably coupled to a constant current alternating current generator; a first secondary coil; and a second secondary coil; a first coolant channel flow meter configured to measure a coolant flow at a first submerged coolant channel, the first submerged coolant channels comprising: the first secondary coil, the primary coil, and the second secondary coil embedded into a cladding walls of the first submerged coolant channel, wherein the primary coil is positioned between the first secondary coil and the second secondary coil, and wherein the first secondary coil, the primary coil, and the second secondary coil are configured in a recessed position into the cladding wall; an electromagnetic interference (EMI) shield embedded in the cladding wall, wherein the EMI shield is configured as a continuous barrier between the cladding wall and the exterior circumferential edge of the first secondary coil, the primary coil, and the second secondary coil; and a hollow center channel configured to pass liquid metal coolant through a center defined by the first secondary coil, the primary coil, and the second secondary coil; a control circuit communicably coupled to the primary coil, the first secondary coil, and the second secondary, wherein the control circuit is configured to: generate a constant current alternating current in the primary coil; determine a voltage difference and a phase difference between the first secondary coil and second secondary coil; and determine a velocity of the liquid metal coolant based on the voltage difference and the phase difference between the first secondary coil and second secondary coil, and the liquid metal coolant composition.

### BRIEF DESCRIPTION OF THE DRAWINGS

FIG. 1 shows a nuclear reactor system comprising a plurality of reactor coolant pumps with an eddy current flow meter embedded in an outlet duct, in accordance with at least one aspect of the present disclosure.

FIG. 2 shows a conventional probe flow meter comprising an eddy current flow measurement circuit.

FIG. 3 shows a coolant channel flow meter comprising a primary coil, a first secondary coil, and a second secondary coil, embedded in a coolant channel cladding wall, in accordance with at least one aspect of the present disclosure.

FIG. 4 shows a block diagram of an ECFM comprising a control circuit communicably coupled to a constant current (CC) alternating current (AC) generator and a secondary coil difference calculator, in accordance with at least one aspect of the present disclosure.

FIG. 5 shows a direct linear relationship between the different value, output signal in mV rms, and the coolant velocity in ft/sec for a sodium liquid metal coolant reactor, in accordance with at least one aspect of the present disclosure.

FIG. 6 shows a test cartridge comprising an ECFM, in accordance with at least one aspect of the present disclosure.

FIG. 7 shows a detailed view of an ECFM in a test cartridge, in accordance with at least one aspect of the present disclosure.

FIG. 8 shows a block diagram of a test cartridge comprising a control circuit and an ECFM, in accordance with at least one aspect of the present disclosure.

FIG. 9 shows a fuel channel assembly comprising a coolant inlet channel, in accordance with at least one aspect of the present disclosure.

FIG. 10 shows a detailed view of the coolant inlet channel, comprising an ECFM integrated into an inlet nozzle of a fuel assembly, in accordance with at least one aspect of the present disclosure.

### DETAILED DESCRIPTION

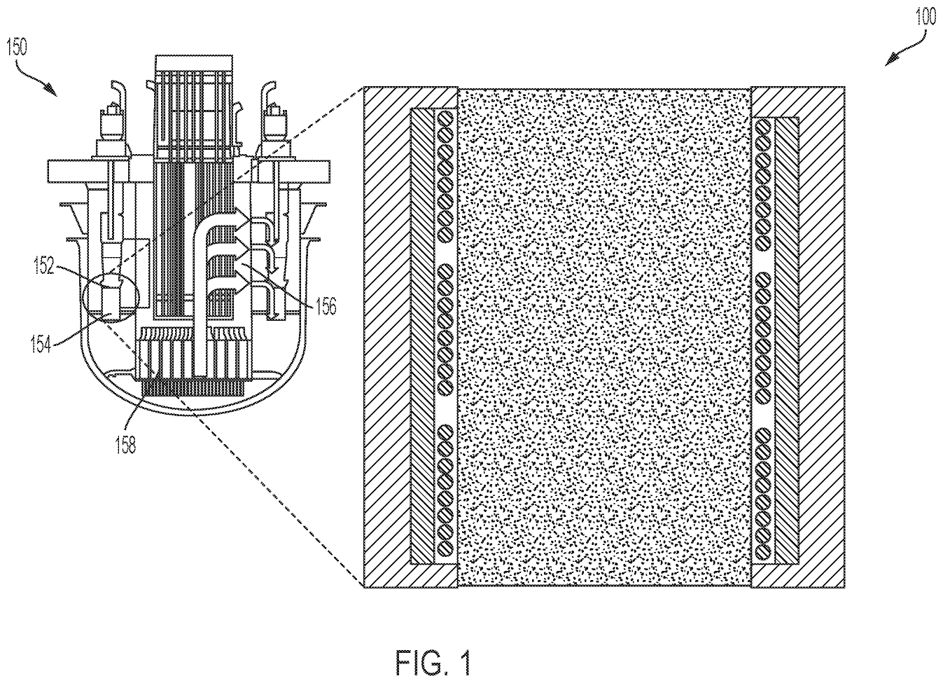

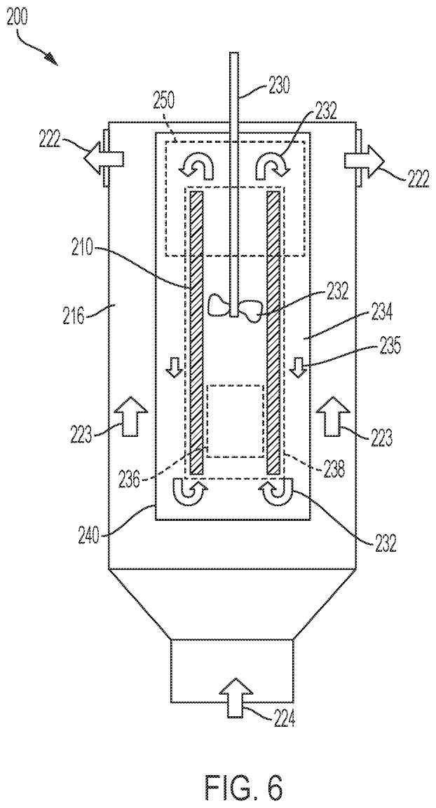

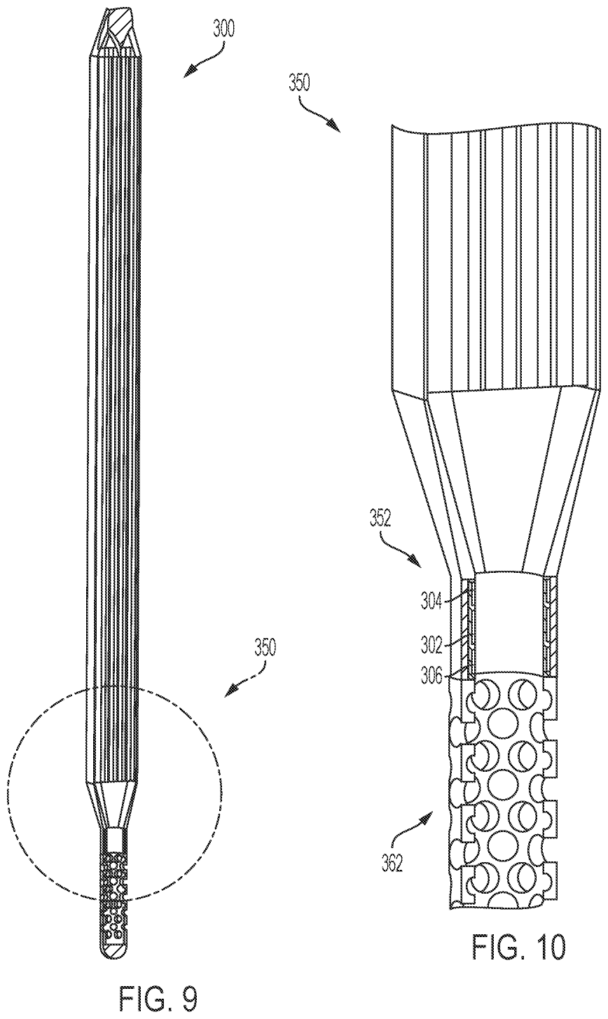

FIG. 1 shows a pool-type nuclear reactor system 150 comprising a plurality of reactor coolant pumps 152 with an eddy current flow meter (ECFM) 100 embedded in an outlet duct 154, in accordance with at least one aspect of the present disclosure. Unlike a loop-type reactor, the coolant channels and primary piping in a pool-type reactor system 150 are not accessible from outside of the reactor and prevent ECFMs 100 from being retrofitted on to the exterior of a coolant channel. Additionally, the ECFMs 100 in pool-type reactor systems 150 are subjected to extreme conditions because they are continuously submerged in corrosive coolant at temperatures in excess of 600° C. The present disclosure describes various aspects of ECFMs 100 that are suited to measure the flow of liquid metal coolant under the harsh conditions of a pool-type channel reactor. The ECFM 100 is a fixed non-invasive design configured to measure the flow velocity of liquid metal coolant as it passes through the center of the coolant channel and through the center of the ECFM 100. The embedded design does not perturb or impede the natural flow of the liquid metal coolant and allows for the ECFM to be implemented in very small coolant channels or ducts. This non-invasive position allows for frequent or continuous coolant flow velocity measurements at an increased measurement accuracy over traditional liquid ECFMs. The embedded ECFM may be implemented in any coolant channel of a nuclear reactor, including but not limited to inlet or outlet channels of fuel assemblies 300 (shown in FIG. 9), reactor pumps 152, primary heat exchanges 156, reactor cores 158, experimental test loops 250 (shown in FIG. 6), or experimental test cartridges 222 and 224 (shown in FIG. 6).

An ECFM is an important element in the experimental test cartridge to monitor and control the flow of coolant. The test cartridge is a closed environment that is configured to regulate the flow of coolant based on a feedback test loop. The test loop and test cartridge subjects an experimental material to different coolant compositions and coolant flow rates in a prototypical irradiation field. The experimental test cartridge allows for the experimental material to be evaluated under actual conditions before the material is implemented in a commercial reactor. The test regions within a commercial reactor are notoriously small and make it difficult to implement a conventional ECFM system.

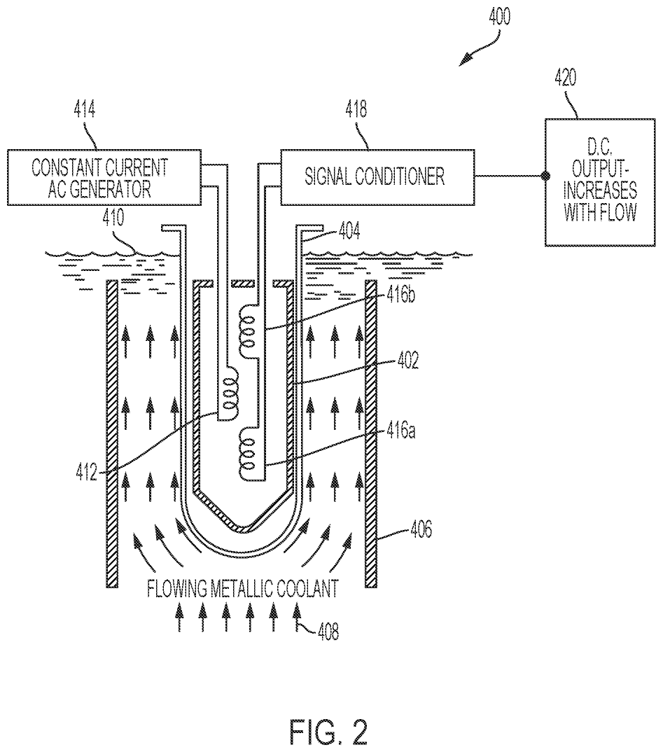

FIG. 2 is a diagram of a conventional ECFM system 400. The conventional ECFM system 400 includes an ECFM probe 402 disposed within a thimble 404 surrounded by a flow duct 406. The ECFM probe 402 measures the flow of a metallic coolant medium 408 in a pool 410 of liquid metal coolant medium 408 that flows within the flow duct 406. The liquid metal coolant medium 408 may be flowing sodium, lead, etc., in a pool of sodium, lead, etc., respectively.

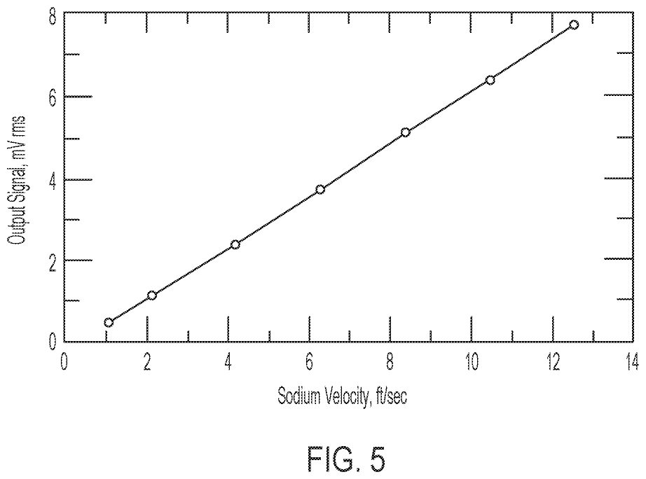

The conventional ECFM probe 402 technology operates using a primary coil 412 that is connected to a voltage source 414, shown as a constant current AC generator, and two secondary coils 416a, 416b that provide an output signal to a signal conditioner circuit 418. When the primary coil 412 is energized with an oscillating voltage generated by the voltage source 414, the primary coil 412 produces a magnetic field that surrounds the primary coil 412. Then, eddy currents are developed in the surrounding metals, including the flowing liquid metal coolant medium 408 (sodium, lead, etc.) At the same time, the magnetic field of the primary coil 412 couples with the secondary coils 416a, b, which are placed adjacent and symmetric to the primary coil 412. When the flow is zero, the voltage generated in each coil 412, 416a, b is equal in magnitude and phase, and when the differential is taken the output voltage is zero. As the flow rate increases, a phase differential is observed between the two secondary coils 416a, b, and the output voltage will increase with an increase in velocity of the molten metallic coolant medium 408. The signal conditioner circuit 408 receives the differential voltage from the secondary coils 416a, b and provides a DC output voltage signal 420 to a control circuit. Accordingly, the DC output voltage signal produced by the signal conditioner circuit 418 increases with an increase in flow of the molten metallic coolant medium 408. This relationship is shown in FIG. 5, for example.

However, the conventional ECFM probe occupies space in the coolant channel and restricts the natural flow of the coolant. Additionally, the ECFM probe is not fixed in place and may experience movement that can decrease the accuracy of flow measurements.

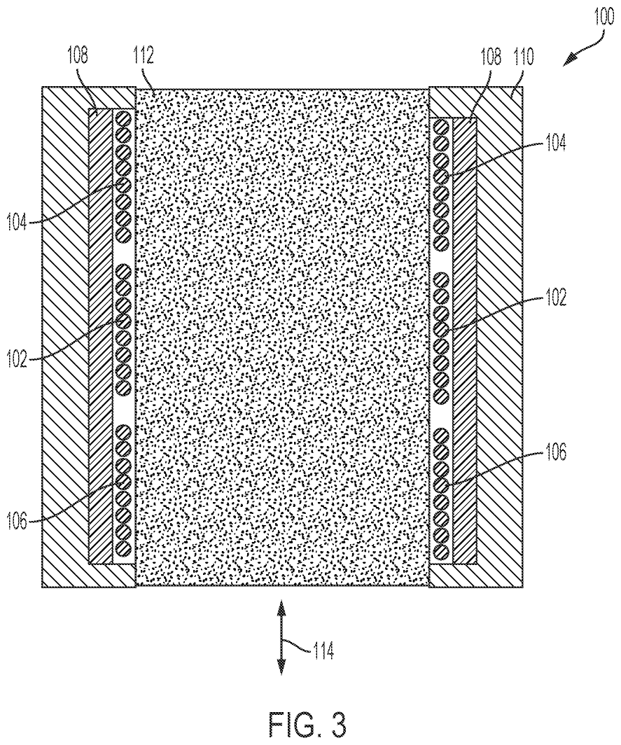

FIG. 3 shows a coolant channel flow meter 100 comprising a primary coil 102, a first secondary coil 104, and a second secondary coil 106, embedded in a coolant channel cladding wall 110, in accordance with at least one aspect of the present disclosure. The coolant channel flow meter may be configured to measure coolant flow velocity in a variety of different locations throughout a nuclear reactor, specifically coolant inlet and outlet points. The velocity of the coolant flow in a channel is measured by the ECFM in the longitudinal direction 114. The ECFM is fixed in place in the coolant channel and coolant flowing outside of the channel may flow in a different direction without impacting the coolant flow measurement. The coolant channel flow meter 100 comprises electromagnetic interference (EMI) shielding 108 on the exterior portion of the channel coils to prevent interference from outside of the channel. The EMI shielding 108 blocks the interference in the magnetic field that is creating by coolant flowing in a different direction outside of the coolant channel.

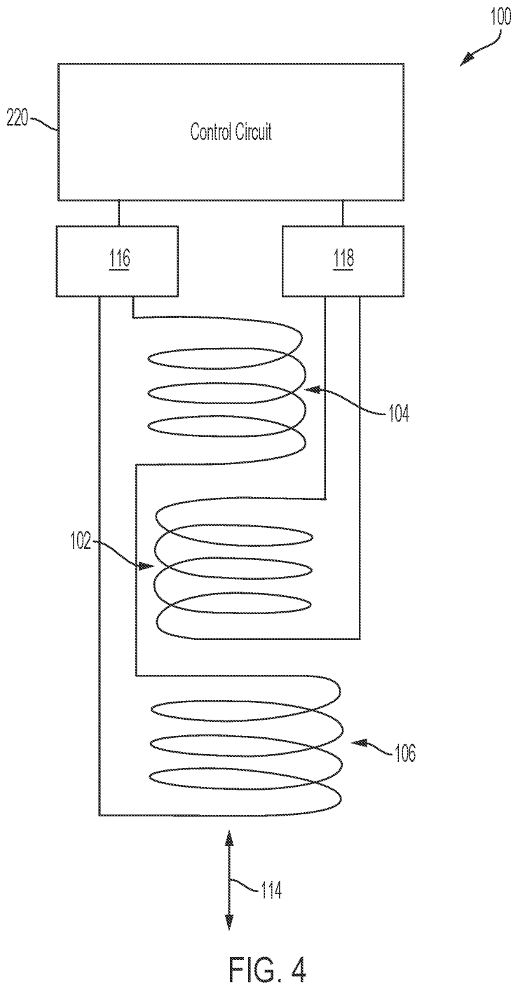

FIG. 4 shows a block diagram of an ECFM comprising a control circuit 120 communicably coupled to a constant current (CC) alternating current (AC) generator 118 and a secondary coil difference calculator 116, in accordance with at least one aspect of the present disclosure. The CC AC generator 118 is communicably coupled to a primary coil 102. The secondary coil difference calculator 116 is communicably coupled a first secondary coil 104 and a second secondary could 106. The control circuit 120 activates the CC AC generator 118, the CC AC generator 118 energizes the primary coil 102, and the primary coil 102 produces a magnetic field in the coolant channel. The magnetic field induces a voltage in the first secondary coil 104 and the second secondary coil 106. When the liquid metal coolant 112 is not moving in the coolant channel, the induced voltage in the first secondary coil 104 and the second secondary coil 106 is equal in phase and magnitude. Thus, when the coolant is not moving, the difference value between the secondary coils is zero and when the coolant is moving, the difference value is a non-zero value. The secondary coil difference calculator 116 transmits the difference value to the control circuit 120, and the control circuit 120 determines the coolant flow velocity. The magnitude of a difference value directly correlates to the flow velocity, and a positive or negative difference value indicates the flow direction.

FIG. 5 illustrates a direct linear relationship between the differential voltage signal, output signal in mV rms, and the velocity of the metallic coolant medium in ft/sec for a sodium liquid metal coolant, for example. In an exemplary aspect, the control circuit uses the linear relationship for liquid metal sodium to determine the coolant velocity at a specific channel in a nuclear reactor. However, different liquid metal compositions have different relationships between the output signal difference values and coolant velocity. The control circuit 120 may be calibrated according to the metal composition relationship so that the ECFM may be used for a variety of different metal compositions. In various aspects, the control circuit may be calibrated to measure the coolant velocity of liquid metal coolant mediums such as lead, lead bismuth eutectic, sodium and potassium, mercury, tin, or other liquid metal coolant mediums used to cool a nuclear reactor core.

In another aspect, FIG. 6 shows a test cartridge 200 comprising an ECFM 250, in accordance with at least one aspect of the present disclosure. The test cartridge 200 operates within a nuclear reactor and comprises a separation barrier 240 that separates the reactor coolant 216 from the test cartridge coolant 234. The test cartridge 200 receives the reactor coolant 216 at an inlet 224, flows through the outer portions 223 of the test cartridge, and returns the reactor coolant 216 through outlet points 222. The test cartridge 200 is configured to evaluate the impact of test coolant flow 234 on the corrosion and erosion of different components under test, in a test region 236. This evaluation process may comprise the use of different liquid metal coolant compositions, coolant flow velocities, or test component composition. The separation barrier 240 allows the test cartridge to experiment with a different coolant compositions and flow velocities without interfering with the active reactor operations. The separation barrier 240 separates the reactor coolant 216 and the test cartridge coolant 234. The coolant flow velocity of the test cartridge coolant 234 is controlled by a propeller 232, via a drive rod 230, in the test cartridge coolant channel 238. FIG. 3 illustrates the coolant flow direction of the test cartridge coolant 234 by arrows 235. However, the test cartridge coolant flow direction is dependent on the rotating direction of the propeller 232 and may be configured to flow in the opposite direction.

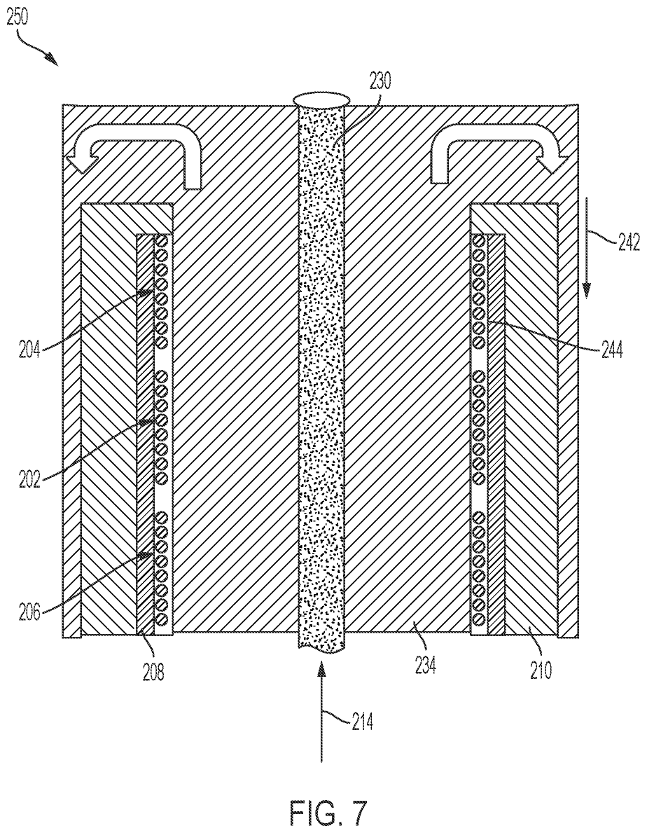

FIG. 7 shows a detailed view of an ECFM 250 in a test cartridge 200, in accordance with at least one aspect of the present disclosure. The propeller drive rod 230 is positioned in the center of the test cartridge coolant channel 238 to engage the propeller 232 and create a coolant flow in the longitudinal direction 214. The ECFM 250 comprises a primary coil 202, a first secondary coil 204, a second secondary coil 206, and EMI shielding 208. The EMI shielding 208 is positioned around the exterior circumferential edge 244 of the coils 202, 204, 206, between the cladding wall 210. The EMI shielding prevents interference from the liquid metal coolant 234 flowing in the opposite direction 242 of the measured flow 214.

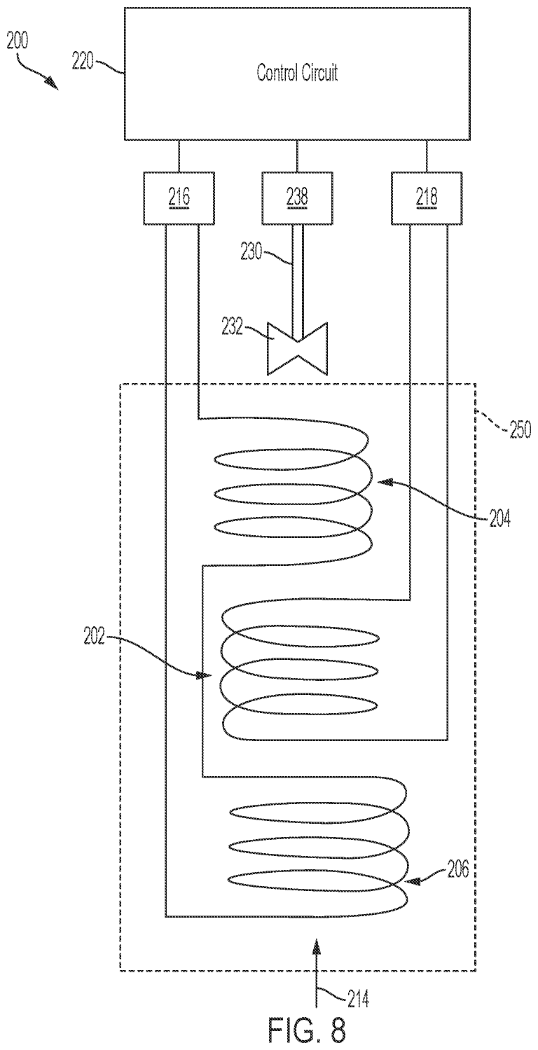

FIG. 8 shows a block diagram of a test cartridge 200 comprising a control circuit 220 and an ECFM 250, in accordance with at least one aspect of the present disclosure. The control circuit 220 is communicably coupled to a constant current AC generator 218, a secondary coil difference calculator 216, and a propeller drive motor 238. The CC AC generator 218 is communicably coupled to the primary coil 202 to generate a magnetic field. The difference calculator 216 is communicably coupled to the first secondary coil 204 and the second secondary coil 206 to determine the difference in the induced voltage of the secondary coils 204 206. The propeller drive motor 238 is configured to engage the propeller 232 though the drive rod 230 according to a predetermined coolant flow velocity. The control circuit 220 determines the liquid metal flow velocity based on the difference value received from the secondary coil difference calculator 216. The control circuit 220 may adjust the coolant flow velocity in the test cartridge through a feedback loop with the propeller drive motor 238 and the secondary coil difference calculator 216.

In another aspect of the disclosure, FIG. 9 shows a fuel channel assembly 300 comprising a coolant inlet channel 350, in accordance with at least one aspect of the present disclosure. FIG. 10 shows a detailed view of the coolant inlet channel 350, comprising an ECFM 352 integrated into an inlet nozzle 362 of a fuel assembly 300, in accordance with at least one aspect of the present disclosure. ECFM 352 comprises a primary coil 302, a first secondary coil 304, and a second secondary coil 306. The ECFM 352 is configured to measure the liquid metal coolant flow at the inlet nozzle 362 and prevent a coolant bottleneck, prior to entering the fuel assembly 300. The non-invasive configuration allows the coolant flow to be accurately measured without altering the flow or velocity of the coolant.

Various aspects of the subject matter described herein are set out in the following numbered examples:

Example 1: A coolant channel flow meter for measuring the velocity of liquid metal coolant comprising: a primary coil communicably coupled to a constant current alternating current generator; a first secondary coil; a second secondary coil; a coolant channel comprising: the first secondary coil, the primary coil, and the second secondary coil embedded into a cladding walls of the coolant channel, wherein the primary coil is positioned between the first secondary coil and the second secondary coil, and wherein the first secondary coil, the primary coil, and the second secondary coil are configured in a recessed position into the cladding wall; an electromagnetic interference (EMI) shield embedded in the cladding wall, wherein the EMI shield is configured as a continuous barrier between the cladding wall and the exterior circumferential edge of the first secondary coil, the primary coil, and the second secondary coil; and a hollow center channel configured to pass liquid metal coolant through a center defined by the first secondary coil, the primary coil, and the second secondary coil; a control circuit communicably coupled to the primary coil, the first secondary coil, and the second secondary, wherein the control circuit is configured to: generate a constant current alternating current in the primary coil; determine a voltage difference and a phase difference between the first secondary coil and second secondary coil; and determine a velocity of the liquid metal coolant based on the voltage difference and the phase difference between the first secondary coil and second secondary coil, and the liquid metal coolant composition.

Example 2: The coolant channel flow meter of Example 1, wherein the recessed position of the first secondary coil, the primary coil, and the second secondary coil does not protrude into the coolant channel.

Example 3: The coolant channel flow meter of Examples 1 and/or 2, wherein the hollow center channel is an inlet for a fuel assembly nozzle.

Example 4: A test cartridge flow meter for measuring the velocity of test cartridge liquid metal coolant comprising: a primary coil communicably coupled to a constant current alternating current generator; a first secondary coil; a second secondary coil; a propeller drive motor configured to actuate a propeller; a coolant channel comprising: the first secondary coil, the primary coil, and the second secondary coil embedded into a cladding walls of the coolant channel, wherein the primary coil is positioned between the first secondary coil and the second secondary coil, and wherein the first secondary coil, the primary coil, and the second secondary coil are configured in a recessed position into the cladding wall; an electromagnetic interference (EMI) shield embedded in the cladding wall, wherein the EMI shield is configured as a continuous barrier between the cladding wall and the exterior circumferential edge of the first secondary coil, the primary coil, and the second secondary coil; and a hollow center channel configured to allow test cartridge liquid metal coolant to pass through a center defined by the first secondary coil, the primary coil, and the second secondary coil; a control circuit communicably coupled to the primary coil, the first secondary coil, and the second secondary, and the control circuit is configured to: engage the propeller drive motor according to a predetermined coolant velocity; generate a constant current alternating current in the primary coil; determine a voltage differential and a phase differential between the first secondary coil and second secondary coil; and determine a velocity of the liquid metal coolant based on the voltage differential and the phase differential between the first secondary coil and second secondary coil, and the liquid metal coolant composition.

Example 5: The test cartridge flow meter of Example 4, wherein the test cartridge liquid metal coolant is a different metal composition than main reactor liquid metal coolant, and wherein the test cartridge liquid metal coolant and the main reactor liquid metal coolant are separated by a separation barrier.

Example 6: The test cartridge flow meter of Examples 4 and/or 5, wherein control circuit is further configured to determine the test cartridge liquid metal coolant velocity and adjust the motor speed to achieve the predetermined coolant velocity.

Example 7: A system for measuring the flow of liquid metal coolant in a pool-type nuclear reactor, the system comprising: a pool-type nuclear reactor comprising a plurality of submerged coolant channels, the plurality of submerged coolant channels comprising one or more coolant channel flow meters; the one or more coolant channel flow meters comprising: a primary coil communicably coupled to a constant current alternating current generator; a first secondary coil; and a second secondary coil; a first coolant channel flow meter configured to measure a coolant flow at a first submerged coolant channel, the first submerged coolant channels comprising: the first secondary coil, the primary coil, and the second secondary coil embedded into a cladding walls of the first submerged coolant channel, wherein the primary coil is positioned between the first secondary coil and the second secondary coil, and wherein the first secondary coil, the primary coil, and the second secondary coil are configured in a recessed position into the cladding wall; an electromagnetic interference (EMI) shield embedded in the cladding wall, wherein the EMI shield is configured as a continuous barrier between the cladding wall and the exterior circumferential edge of the first secondary coil, the primary coil, and the second secondary coil; and a hollow center channel configured to pass liquid metal coolant through a center defined by the first secondary coil, the primary coil, and the second secondary coil; a control circuit communicably coupled to the primary coil, the first secondary coil, and the second secondary, wherein the control circuit is configured to: generate a constant current alternating current in the primary coil; determine a voltage difference and a phase difference between the first secondary coil and second secondary coil; and determine a velocity of the liquid metal coolant based on the voltage difference and the phase difference between the first secondary coil and second secondary coil, and the liquid metal coolant composition.

Example 8: The system of Example 7, wherein the recessed position of the first secondary coil, the primary coil, and the second secondary coil does not protrude into the first submerged coolant channel.

Example 9: The system of Examples 7 and/or 8, wherein the hollow center channel is an inlet for a fuel assembly nozzle.

Example 10: The system of Examples 7, 8, and/or 9, further comprising a second coolant channel flow meter configured to measure the coolant flow at a second submerged coolant channel.

Example 11: The system of Examples 7, 8, 9, and/or 10, further comprising a second coolant channel flow meter configured to measure the coolant flow at a test cartridge.

Numerous specific details are set forth to provide a thorough understanding of the overall structure, function, manufacture, and use of the aspects as described in the present disclosure and illustrated in the accompanying drawings. Well-known operations, components, and elements have not been described in detail so as not to obscure the aspects described in the present disclosure. The reader will understand that the aspects described and illustrated herein are non-limiting examples, and thus it can be appreciated that the specific structural and functional details disclosed herein may be representative and illustrative. Variations and changes thereto may be made without departing from the scope of the claims. Furthermore, it is to be understood that such terms as “forward”, “rearward”, “left”, “right”, “upwardly”, “downwardly”, and the like are words of convenience and are not to be construed as limiting terms.

In the present disclosure, like reference characters designate like or corresponding parts throughout the several views of the drawings.

All patents, patent applications, publications, or other disclosure material mentioned herein, are hereby incorporated by reference in their entirety as if each individual reference was expressly incorporated by reference respectively. All references, and any material, or portion thereof, that are said to be incorporated by reference herein are incorporated herein only to the extent that the incorporated material does not conflict with existing definitions, statements, or other disclosure material set forth in this disclosure. As such, and to the extent necessary, the disclosure as set forth herein supersedes any conflicting material incorporated herein by reference and the disclosure expressly set forth in the present application controls.

The present disclosure has been described with reference to various examples and illustrative aspects. The aspects described herein are understood as providing illustrative features of varying detail of various aspects of the present disclosure; and therefore, unless otherwise specified, it is to be understood that, to the extent possible, one or more features, elements, components, constituents, ingredients, structures, modules, and/or aspects of the disclosed aspects may be combined, separated, interchanged, and/or rearranged with or relative to one or more other features, elements, components, constituents, ingredients, structures, modules, and/or aspects of the disclosed aspects without departing from the scope of the present disclosure. Accordingly, it will be recognized by persons having ordinary skill in the art that various substitutions, modifications or combinations of any of the example aspects may be made without departing from the scope of the present disclosure. In addition, persons skilled in the art will recognize, or be able to ascertain using no more than routine experimentation, many equivalents to the various aspects of the present disclosure described herein upon review of the present disclosure. Thus, the present disclosure is not limited by the description of the various aspects, but rather by the claims.

It should further be noted that the implementations of the control circuit 120, 220, described above are merely for illustrative purposes and should not be interpreted to be limiting in any way. The control circuit 120, 220, can be utilized in a variety of different processing contexts.

While several forms have been illustrated and described, it is not the intention of Applicant to restrict or limit the scope of the appended claims to such detail. Numerous modifications, variations, changes, substitutions, combinations, and equivalents to those forms may be implemented and will occur to those skilled in the art without departing from the scope of the present disclosure. Moreover, the structure of each element associated with the described forms can be alternatively described as a means for providing the function performed by the element. Also, where materials are disclosed for certain components, other materials may be used. It is therefore to be understood that the foregoing description and the appended claims are intended to cover all such modifications, combinations, and variations as falling within the scope of the disclosed forms. The appended claims are intended to cover all such modifications, variations, changes, substitutions, modifications, and equivalents.

The foregoing detailed description has set forth various forms of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, and/or examples can be implemented, individually and/or collectively, by a wide range of hardware, software, firmware, or virtually any combination thereof. Those skilled in the art will recognize that some aspects of the forms disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and or firmware would be well within the skill of one of skill in the art in light of this disclosure. In addition, those skilled in the art will appreciate that the mechanisms of the subject matter described herein are capable of being distributed as one or more program products in a variety of forms, and that an illustrative form of the subject matter described herein applies regardless of the particular type of signal bearing medium used to actually carry out the distribution.

Instructions used to program logic to perform various disclosed aspects can be stored within a memory in the system, such as dynamic random access memory (DRAM), cache, flash memory, or other storage. Furthermore, the instructions can be distributed via a network or by way of other computer readable media. Thus a machine-readable medium may include any mechanism for storing or transmitting information in a form readable by a machine (e.g., a computer), such as floppy diskettes, optical disks, compact disc, read-only memory (CD-ROMs), and magneto-optical disks, read-only memory (ROMs), random access memory (RAM), erasable programmable read-only memory (EPROM), electrically erasable programmable read-only memory (EEPROM), magnetic or optical cards, flash memory, or a tangible, machine-readable storage used in the transmission of information over the Internet via electrical, optical, acoustical or other forms of propagated signals (e.g., carrier waves, infrared signals, digital signals, etc.). Accordingly, the non-transitory computer-readable medium includes any type of tangible machine-readable medium suitable for storing or transmitting electronic instructions or information in a form readable by a machine (e.g., a computer).

As used in any aspect herein, the term “control circuit” may refer to, for example, hardwired circuitry, programmable circuitry (e.g., a computer processor including one or more individual instruction processing cores, processing unit, processor, microcontroller, microcontroller unit, controller, digital signal processor (DSP), programmable logic device (PLD), programmable logic array (PLA), or field programmable gate array (FPGA)), state machine circuitry, firmware that stores instructions executed by programmable circuitry, quantum processors, spiking network hardware, and any combination thereof. The control circuit may, collectively or individually, be embodied as circuitry that forms part of a larger system, for example, an integrated circuit (IC), an application-specific integrated circuit (ASIC), a system on-chip (SoC), desktop computers, laptop computers, tablet computers, servers, smart phones, etc. Accordingly, as used herein “control circuit” includes, but is not limited to, electrical circuitry having at least one discrete electrical circuit, electrical circuitry having at least one integrated circuit, electrical circuitry having at least one application specific integrated circuit, electrical circuitry forming a general purpose computing device configured by a computer program (e.g., a general purpose computer configured by a computer program which at least partially carries out processes and/or devices described herein, or a microprocessor configured by a computer program which at least partially carries out processes and/or devices described herein), electrical circuitry forming a memory device (e.g., forms of RAM), and/or electrical circuitry forming a communications device (e.g., a modem, communications switch, or optical-electrical equipment). Those having skill in the art will recognize that the subject matter described herein may be implemented in an analog or digital fashion or some combination thereof.

As used in any aspect herein, the term “logic” may refer to an app, software, firmware, and/or circuitry configured to perform any of the aforementioned operations. Software may be embodied as a software package, code, instructions, instruction sets, and/or data recorded on non-transitory computer readable storage medium. Firmware may be embodied as code, instructions or instruction sets and/or data that are hard-coded (e.g., nonvolatile) in memory devices.

As used in any aspect herein, the terms “component,” “system,” “module,” and the like can refer to a computer-related entity, either hardware, a combination of hardware and software, software, or software in execution.

As used in any aspect herein, an “algorithm” refers to a self-consistent sequence of steps leading to a desired result, where a “step” refers to a manipulation of physical quantities and/or logic states which may, though need not necessarily, take the form of electrical or magnetic signals capable of being stored, transferred, combined, compared, and otherwise manipulated. It is common usage to refer to these signals as bits, values, elements, symbols, characters, terms, numbers, or the like. These and similar terms may be associated with the appropriate physical quantities and are merely convenient labels applied to these quantities and/or states.

Unless specifically stated otherwise as apparent from the foregoing disclosure, it is appreciated that, throughout the foregoing disclosure, discussions using terms such as “processing,” “computing,” “calculating,” “determining,” “displaying,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission, or display devices.

One or more components may be referred to herein as “configured to,” “configurable to,” “operable/operative to,” “adapted/adaptable,” “able to,” “conformable/conformed to,” etc. Those skilled in the art will recognize that “configured to” can generally encompass active-state components and/or inactive-state components and/or standby-state components, unless context requires otherwise.

Those skilled in the art will recognize that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to claims containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that typically a disjunctive word and/or phrase presenting two or more alternative terms, whether in the description, claims, or drawings, should be understood to contemplate the possibilities of including one of the terms, either of the terms, or both terms unless context dictates otherwise. For example, the phrase “A or B” will be typically understood to include the possibilities of “A” or “B” or “A and B.”

With respect to the appended claims, those skilled in the art will appreciate that recited operations therein may generally be performed in any order. Also, although claim recitations are presented in a sequence(s), it should be understood that the various operations may be performed in other orders than those which are described, or may be performed concurrently.

Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

It is worthy to note that any reference to “one aspect,” “an aspect,” “an exemplification,” “one exemplification,” and the like means that a particular feature, structure, or characteristic described in connection with the aspect is included in at least one aspect. Thus, appearances of the phrases “in one aspect,” “in an aspect,” “in an exemplification,” and “in one exemplification” in various places throughout the present disclosure are not necessarily all referring to the same aspect. Furthermore, the particular features, structures or characteristics may be combined in any suitable manner in one or more aspects.

As used herein, the singular form of “a”, “an”, and “the” include the plural references unless the context clearly dictates otherwise.

Directional phrases used herein, such as, for example and without limitation, top, bottom, left, right, lower, upper, front, back, and variations thereof, shall relate to the orientation of the elements shown in the accompanying drawing and are not limiting upon the claims unless otherwise expressly stated.

The terms “about” or “approximately” as used in the present disclosure, unless otherwise specified, means an acceptable error for a particular value as determined by one of ordinary skill in the art, which depends in part on how the value is measured or determined. In certain aspects, the term “about” or “approximately” means within 1, 2, 3, or 4 standard deviations. In certain aspects, the term “about” or “approximately” means within 50%, 200%, 105%, 100%, 9%, 8%, 7%, 6%, 5%, 4%, 3%, 2%, 1%, 0.5%, or 0.05% of a given value or range.

In the present disclosure, unless otherwise indicated, all numerical parameters are to be understood as being prefaced and modified in all instances by the term “about,” in which the numerical parameters possess the inherent variability characteristic of the underlying measurement techniques used to determine the numerical value of the parameter. At the very least, and not as an attempt to limit the application of the doctrine of equivalents to the scope of the claims, each numerical parameter described herein should at least be construed in light of the number of reported significant digits and by applying ordinary rounding techniques.

Any numerical range recited herein includes all sub-ranges subsumed within the recited range. For example, a range of “1 to 100” includes all sub-ranges between (and including) the recited minimum value of 1 and the recited maximum value of 100, that is, having a minimum value equal to or greater than 1 and a maximum value equal to or less than 100. Also, all ranges recited herein are inclusive of the end points of the recited ranges. For example, a range of “1 to 100” includes the end points 1 and 100. Any maximum numerical limitation recited in the present disclosure is intended to include all lower numerical limitations subsumed therein, and any minimum numerical limitation recited in the present disclosure is intended to include all higher numerical limitations subsumed therein. Accordingly, Applicant reserves the right to amend the present disclosure, including the claims, to expressly recite any sub-range subsumed within the ranges expressly recited. All such ranges are inherently described in the present disclosure.

Any patent application, patent, non-patent publication, or other disclosure material referred to in the present disclosure and/or listed in any Application Data Sheet is incorporated by reference herein, to the extent that the incorporated materials is not inconstant herewith. As such, and to the extent necessary, the disclosure as explicitly set forth herein supersedes any conflicting material incorporated herein by reference. Any material, or portion thereof, that is said to be incorporated by reference herein, but which conflicts with existing definitions, statements, or other disclosure material set forth herein will only be incorporated to the extent that no conflict arises between that incorporated material and the existing disclosure material.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system that “comprises,” “has,” “includes” or “contains” one or more elements possesses those one or more elements, but is not limited to possessing only those one or more elements. Likewise, an element of a system, device, or apparatus that “comprises,” “has,” “includes” or “contains” one or more features possesses those one or more features, but is not limited to possessing only those one or more features.

In summary, numerous benefits have been described which result from employing the concepts described herein. The foregoing description of the one or more forms has been presented for purposes of illustration and description. It is not intended to be exhaustive or limiting to the precise form disclosed. Modifications or variations are possible in light of the above teachings. The one or more forms were chosen and described in order to illustrate principles and practical application to thereby enable one of ordinary skill in the art to utilize the various forms and with various modifications as are suited to the particular use contemplated. It is intended that the claims submitted herewith define the overall scope.

What is claimed is:

1. A coolant channel flow meter for measuring the velocity of liquid metal coolant comprising:
a primary coil communicably coupled to a constant current alternating current generator;
a first secondary coil;
a second secondary coil;
a coolant channel comprising:
the first secondary coil, the primary coil, and the second secondary coil embedded into a cladding walls of the coolant channel, wherein the primary coil is positioned between the first secondary coil and the second secondary coil, and wherein the first secondary coil, the primary coil, and the second secondary coil are configured in a recessed position into the cladding wall;
an electromagnetic interference (EMI) shield embedded in the cladding wall, wherein the EMI shield is configured as a continuous barrier between the cladding wall and the exterior circumferential edge of the first secondary coil, the primary coil, and the second secondary coil; and
a hollow center channel configured to pass liquid metal coolant through a center defined by the first secondary coil, the primary coil, and the second secondary coil;
a control circuit communicably coupled to the primary coil, the first secondary coil, and the second secondary, wherein the control circuit is configured to:
generate a constant current alternating current in the primary coil;
determine a voltage difference and a phase difference between the first secondary coil and second secondary coil; and
determine a velocity of the liquid metal coolant based on the voltage difference and the phase difference between the first secondary coil and second secondary coil, and the liquid metal coolant composition.

2. The coolant channel flow meter of claim 1, wherein the recessed position of the first secondary coil, the primary coil, and the second secondary coil does not protrude into the coolant channel.

3. The coolant channel flow meter of claim 1, wherein the hollow center channel is an inlet for a fuel assembly nozzle.

4. A test cartridge flow meter for measuring the velocity of test cartridge liquid metal coolant comprising:
a primary coil communicably coupled to a constant current alternating current generator;
a first secondary coil;
a second secondary coil;
a propeller drive motor configured to actuate a propeller;
a coolant channel comprising:
the first secondary coil, the primary coil, and the second secondary coil embedded into a cladding walls of the coolant channel, wherein the primary coil is positioned between the first secondary coil and the second secondary coil, and wherein the first secondary coil, the primary coil, and the second secondary coil are configured in a recessed position into the cladding wall;
an electromagnetic interference (EMI) shield embedded in the cladding wall, wherein the EMI shield is configured as a continuous barrier between the cladding wall and the exterior circumferential edge of the first secondary coil, the primary coil, and the second secondary coil; and
a hollow center channel configured to allow test cartridge liquid metal coolant to pass through a center defined by the first secondary coil, the primary coil, and the second secondary coil;
a control circuit communicably coupled to the primary coil, the first secondary coil, and the second secondary, and the control circuit is configured to:
engage the propeller drive motor according to a predetermined coolant velocity;
generate a constant current alternating current in the primary coil;
determine a voltage differential and a phase differential between the first secondary coil and second secondary coil; and
determine a velocity of the liquid metal coolant based on the voltage differential and the phase differential between the first secondary coil and second secondary coil, and the liquid metal coolant composition.

5. The test cartridge flow meter of claim 4, wherein the test cartridge liquid metal coolant is a different metal composition than main reactor liquid metal coolant, and wherein the test cartridge liquid metal coolant and the main reactor liquid metal coolant are separated by a separation barrier.

6. The test cartridge flow meter of claim 4, wherein control circuit is further configured to determine the test cartridge liquid metal coolant velocity and adjust the motor speed to achieve the predetermined coolant velocity.

7. A system for measuring the flow of liquid metal coolant in a pool-type nuclear reactor, the system comprising:
a pool-type nuclear reactor comprising a plurality of submerged coolant channels, the plurality of submerged coolant channels comprising one or more coolant channel flow meters;
the one or more coolant channel flow meters comprising:
a primary coil communicably coupled to a constant current alternating current generator;
a first secondary coil; and
a second secondary coil;
a first coolant channel flow meter configured to measure a coolant flow at a first submerged coolant channel, the first submerged coolant channels comprising:
the first secondary coil, the primary coil, and the second secondary coil embedded into a cladding walls of the first submerged coolant channel, wherein the primary coil is positioned between the first secondary coil and the second secondary coil, and wherein the first secondary coil, the primary coil, and the second secondary coil are configured in a recessed position into the cladding wall;
an electromagnetic interference (EMI) shield embedded in the cladding wall, wherein the EMI shield is configured as a continuous barrier between the cladding wall and the exterior circumferential edge of the first secondary coil, the primary coil, and the second secondary coil; and
a hollow center channel configured to pass liquid metal coolant through a center defined by the first secondary coil, the primary coil, and the second secondary coil;
a control circuit communicably coupled to the primary coil, the first secondary coil, and the second secondary, wherein the control circuit is configured to:
generate a constant current alternating current in the primary coil;
determine a voltage difference and a phase difference between the first secondary coil and second secondary coil; and
determine a velocity of the liquid metal coolant based on the voltage difference and the phase difference between the first secondary coil and second secondary coil, and the liquid metal coolant composition.

8. The system of claim 7, wherein the recessed position of the first secondary coil, the primary coil, and the second secondary coil does not protrude into the first submerged coolant channel.

9. The system of claim 7, wherein the hollow center channel is an inlet for a fuel assembly nozzle.

10. The system of claim 7, further comprising a second coolant channel flow meter configured to measure the coolant flow at a second submerged coolant channel.

11. The system of claim 7, further comprising a second coolant channel flow meter configured to measure the coolant flow at a test cartridge.
